(19) United States
(12) Patent Application Publication
(10) Pub. No.: US 2007/0058341 A1
(43) Pub. Date: Mar. 15, 2007

(54) Fan duct

(76) Inventor: Tsung-Te Hsiao, Jhunan Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/223,108

(22) Filed: Sep. 12, 2005

(51) Int. Cl. H05K 7/20

(52) U.S. Cl. 361/695

(57) ABSTRACT

A fan duct is retained on a fan. The fan has an outer frame. The outer frame forms a plurality of cavities in an outer circumferential surface thereof. The fan duct has a main duct wall and a connecting wall. The main duct wall has a fan-end opening. The connecting wall extends outwardly from the fan-end opening of the main duct wall and has at least two hooks. An edge of the outer circumferential surface of the outer frame of the fan matches an inside of the connecting wall, and each of the hooks locks into a corresponding one of the cavities. As a result, the fan duct of the present invention is capable of being easily hung onto the fan, so that the fan duct can be mounted on and detached from the fan without requiring the use of tools.

### BACKGROUND OF THE INVENTION

1. Field of the Invention

The present invention relates to a fan duct, and more particularly, to a fan duct for a heat dissipation module of an electronic product.

2. Background of the Invention

When an electronic product operates, its electronic components generate a large amount of heat. The heat has to be dissipated to reduce the temperature of the electronic components, thereby ensuring that the operations of the electronic components are normal. For example, a central processing unit of a computer processes data at a very fast speed and generates a large amount of heat. The heat has to be dissipated quickly to prevent the computer from crashing. Therefore, an electronic product requires a heat dissipation module to dissipate heat for its electronic components.

A conventional heat dissipation module includes a heat dissipation device (such as a set of heat dissipation fins) and a fan. The fan is mounted on the heat dissipation device. The heat dissipation module is disposed inside a casing of an electronic product, and the heat dissipation device is mounted on an electronic component (such as a central processing unit) of the electronic product. The heat generated by the electronic component is conducted to the heat dissipation device, and the airflow produced by the fan carries the heat and flows outside the casing, thereby dissipating heat for the electronic component.

As there is a gap between the fan and the casing, the airflow remains inside the casing through the gap and is unable to completely flow outside the casing. As a result, the heat dissipation effect of the heat dissipation module is reduced. Therefore, a fan duct is disposed between the fan and the casing, so as to thoroughly guide the airflow outside the casing.

A conventional fan duct has a number of screw holes and a number of hooks. The hooks respectively lock a number of locking holes in a casing of an electronic product, and a number of screws respectively penetrate through a number of through holes in the casing and respectively fasten in the screw holes of the fan duct. As such, the fan duct is fixed on the casing and is disposed between the casing and a fan disposed inside the casing.

When the above conventional fan duct is mounted on the casing or detached from the casing, an appropriate tool that matches the screws has to be prepared. Furthermore, when detached, the screws are lost very easily. Consequently, the assembly and detachment of the fan duct requires a lot of time and work. In addition, the hooks and the screws are exposed outside the casing, detracting from the overall appearance of the casing.

### SUMMARY OF THE INVENTION

The primary object of the invention is therefore to specify a fan duct that is capable of being mounted on and detached from a fan without requiring the use of tools, and that is capable of improving the overall appearance of a casing.

According to the invention, the object is achieved via a fan duct retained on a fan. The fan has an outer frame. The outer frame forms a plurality of cavities in an outer circumferential surface thereof. The fan duct comprises a main duct wall and a connecting wall. The main duct wall has a fan-end opening adjacent to the fan. The connecting wall extends axially and outwardly from the fan-end opening of the main duct wall. The connecting wall has at least two hooks extending radially toward the fan-end opening. An edge of the outer circumferential surface of the outer frame of the fan matches an inside of the connecting wall, and each of the hooks locks into a corresponding one of the cavities.

The connecting wall and the hooks enable the fan duct of the present invention to be hung onto the fan easily, so that the fan duct is capable of being mounted on and detached from the fan without requiring the use of tools. In addition, instead of being fixed on a casing of an electronic product, the fan duct of the present invention is fixed on the fan, thereby improving the overall appearance of the casing.

To provide a further understanding of the invention, the following detailed description illustrates embodiments and examples of the invention. Examples of the more important features of the invention have thus been summarized rather broadly in order that the detailed description thereof that follows may be better understood, and in order that the contributions to the art may be appreciated. There are, of course, additional features of the invention which will be described hereinafter and which will form the subject of the claims appended hereto.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a perspective view of a first embodiment of a fan duct of the present invention;

FIG. 2 is a side view of a first embodiment of a fan duct of the present invention;

FIG. 3 is an exploded perspective view of a first embodiment of a fan duct of the present invention and a fan;

FIG. 4 is a perspective assembly view of a first embodiment of a fan duct of the present invention and a fan;

FIG. 5 is a cross-sectional view of a first embodiment of a fan duct of the present invention and a fan;

FIG. 6 is a perspective assembly view of a heat dissipation module having a first embodiment of a fan duct of the present invention;

FIG. 7 is a perspective view of a second embodiment of a fan duct of the present invention;

FIG. 8 is a perspective view of a third embodiment of a fan duct of the present invention;

FIG. 9 is a perspective view of a fourth embodiment of a fan duct of the present invention; and

FIG. 10 is a perspective view of a fifth embodiment of a fan duct of the present invention.

### DETAILED DESCRIPTION OF THE EMBODIMENTS

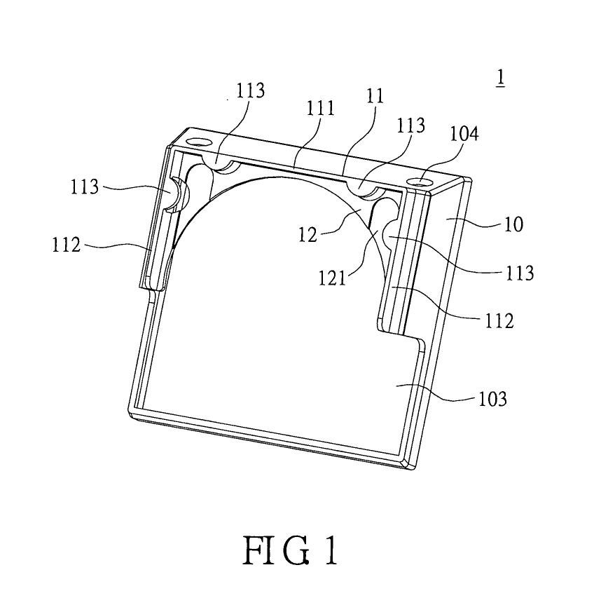

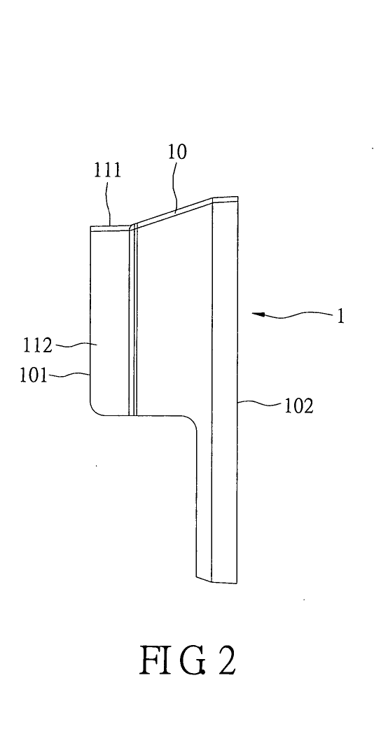

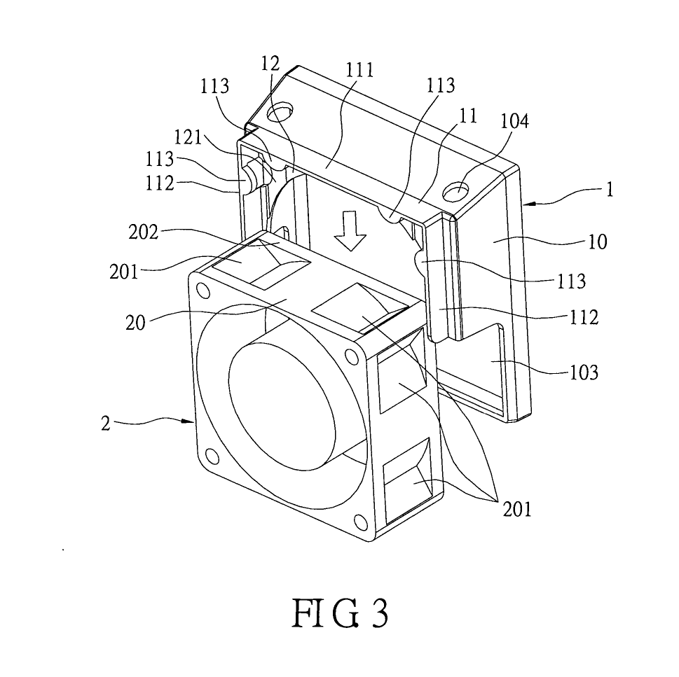

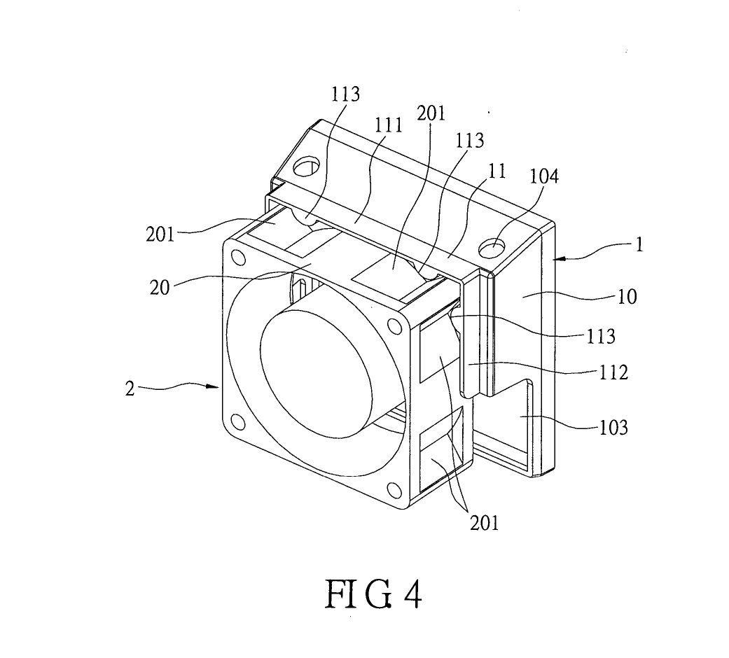

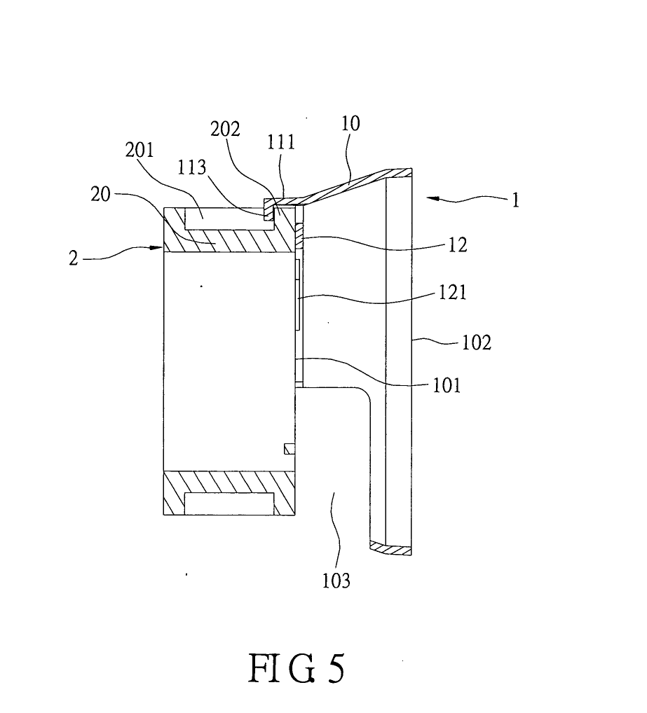

FIG. 1 and FIG. 2 show a first embodiment of the present invention. The present invention provides a fan duct 1. Referring to FIGS. 3-5, the fan duct 1 is retained on a fan 2. The fan duct 1 comprises a main duct wall 10, a connecting wall 11, and an inner baffle 12.

The main duct wall 10 has a fan-end opening 101 adjacent to the fan 2 and a casing-end opening 102 adjacent to a casing (not shown). The main duct wall 10 further forms a cutout 103 in a bottom portion of the fan-end opening 101. The main duct wall 10 further has a through hole 104 disposed in an upper portion thereof.

The connecting wall 11 extends axially and outwardly from the fan-end opening 101 of the main duct wall 10. As shown in FIG. 1, the connecting wall 11 has an upper wall 111 and two lateral walls 112. In addition, the connecting wall 11 has at least two hooks 113 extending radially toward the fan-end opening 101. In the first embodiment, the at least two hooks 113 have a quantity of four. Two of the hooks 113 are respectively disposed close to two ends of the upper wall 111, and the other two hooks 113 are respectively disposed close to top ends of the two lateral walls 112.

The inner baffle 12 extends radially from the main duct wall 10 toward the fan-end opening 101. The inner baffle 12 has a guiding slot 121 facing the fan 2.

The structure of the fan duct 1 is elastically deformable. Alternatively, the fan duct 1 may be made of a soft material (such as soft plastic having elasticity).

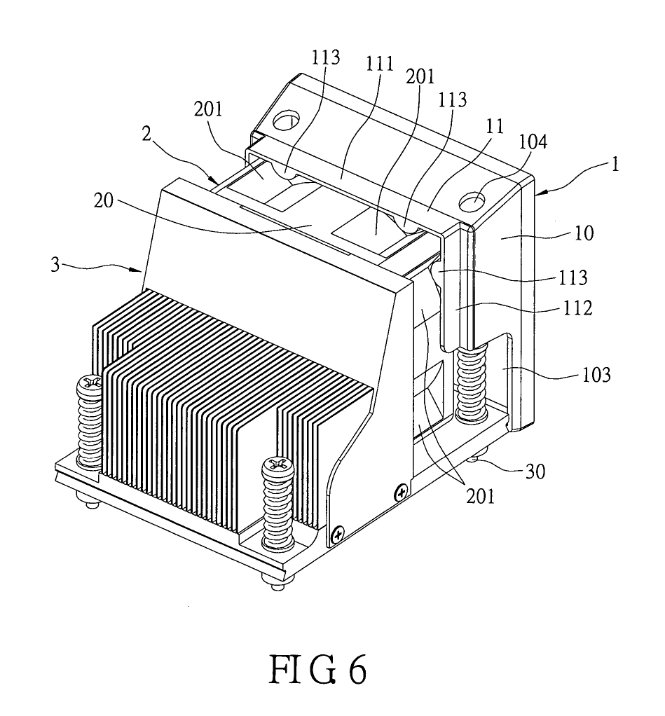

Referring to FIG. 6, the fan 2 is firstly fixed to a heat dissipation device 3 via screws (not shown). Next, the fan duct 1 is hung onto the fan 2, so that the fan duct 1 of the present invention, the fan 2, and the heat dissipation device 3 are assembled to form a heat dissipation module.

As shown in FIGS. 3-5, the fan 2 has an outer frame 20. The outer frame 20 forms a plurality of cavities 201 in an outer circumferential surface thereof. When assembling the fan duct 1 and the fan 2, an edge 202 of the outer circumferential surface of the outer frame 20 of the fan 2 matches an inside of the connecting wall 11, and each of the hooks 113 locks into a corresponding one of the cavities 201, so that the edge 202 of the outer circumferential surface of the outer frame 20 of the fan 2 is clipped between the inner baffle 12 and the at least two hooks 113. In addition, the guiding slot 121 of the inner baffle 12 guides the screw-head of the screw that fixes the fan 2 to the heat dissipation device 3, and the screw-head slightly presses against the inner baffle 12 to prevent the fan duct 1 from shaking. Therefore, the fan duct 1 of the present invention is capable of being hung onto the fan 2 simply due to its characteristics of being made of soft material and its structure, so that the fan duct 1 can be mounted on and detached from the fan 2 without requiring the use of tools.

The heat dissipation module is disposed inside a casing (not shown) of an electronic product. Referring to FIG. 6, a tool (not shown) fastens a fastener 30 of the heat dissipation device 3 to the electronic product through the through hole 104 of the fan duct 1, so that the heat dissipation device 3 is mounted on an electronic component (such as a central processing unit) of the electronic product, and so that the casing-end opening 102 of the main duct wall 10 of the fan duct 1 is adjacent to heat dissipation holes of the casing. The heat generated by the electronic component is conducted to the heat dissipation device 3, and the airflow produced by the fan 2 carries the heat and flows outside the casing through the fan duct 1, thereby dissipating heat for the electronic component. In addition, the cutout 103 of the main duct wall 10 further guides air around the fan 2, thereby improving the heat dissipation effect of the heat dissipation module. The hooks 113 may also retain the power wire (not shown) of the fan 2.

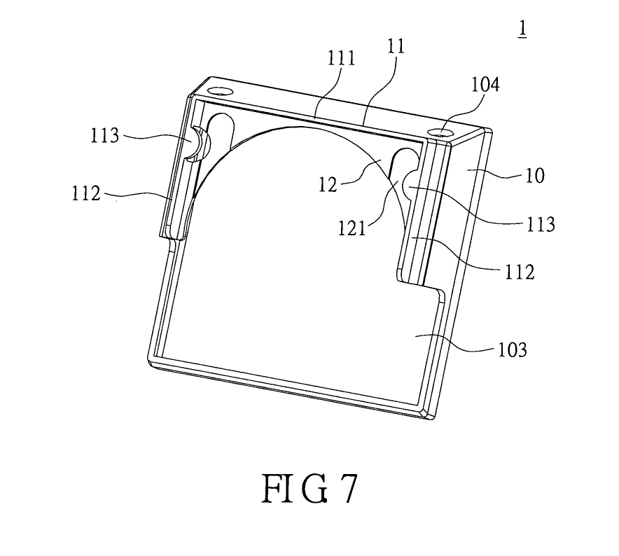

FIG. 7 shows a second embodiment of the present invention. In the second embodiment, the at least two hooks 113 are respectively disposed close to top ends of the two lateral walls 112.

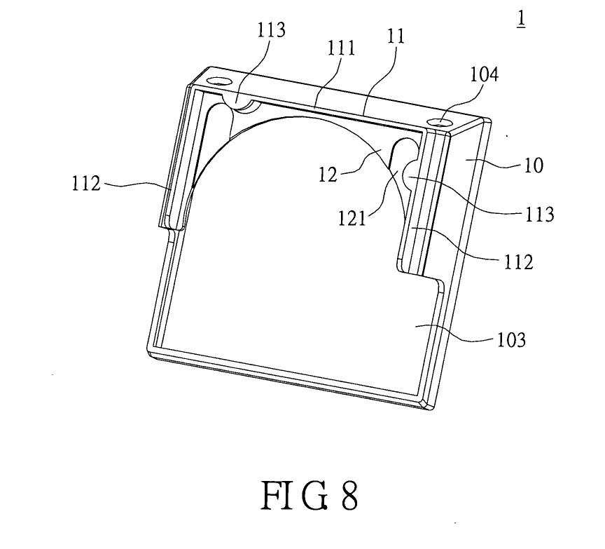

FIG. 8 shows a third embodiment of the present invention. In the third embodiment, the at least two hooks 113 are respectively disposed close to an end of the upper wall 111 and a top end of one of the lateral walls 112.

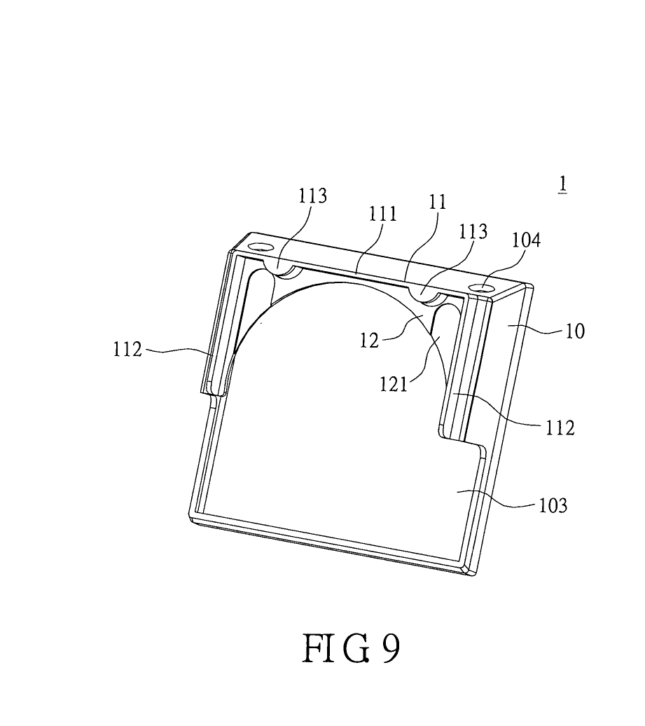

FIG. 9 shows a fourth embodiment of the present invention. In the fourth embodiment, the at least two hooks 113 are respectively disposed close to two ends of the upper wall 111.

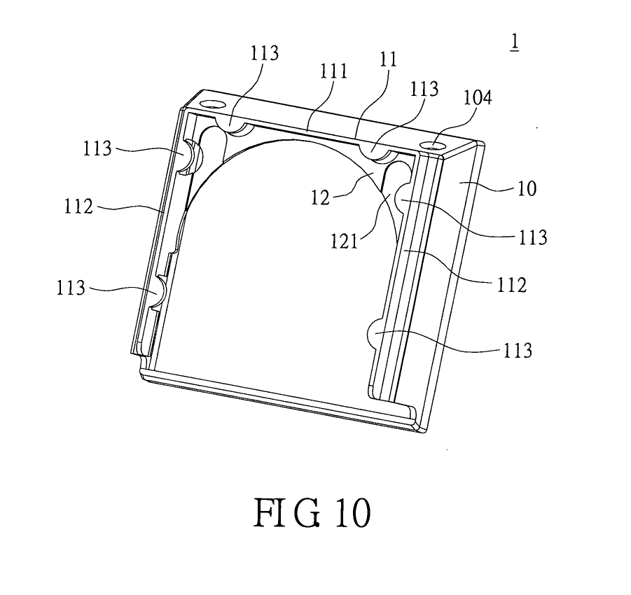

FIG. 10 shows a fifth embodiment of the present invention. In the fifth embodiment, the at least two hooks 113 have a quantity of six. Two of the hooks 113 are respectively disposed close to two ends of the upper wall 111, and the other four of the hooks 113 are respectively disposed close to four ends of the two lateral walls 112. In addition, as shown in FIG. 10, the main duct wall 10 does not form a cutout 103 like the first embodiment.

According to the above embodiments, the hooks 113 may be disposed at the upper wall 111 and/or the lateral walls 112 of the connecting wall 11 to achieve the object of the present invention that allows the fan duct 1 to be retained on the fan 2 simply and reliably. In addition, instead of being fixed on the casing of the electronic product, the fan duct 1 of the present invention is fixed on the fan 2, thereby improving the overall appearance of the casing.

As indicated above, the fan duct of the present invention has the following advantages:

1. The connecting wall and the hooks enable the fan duct of the present invention to be hung onto the fan easily, so that the fan duct is capable of being mounted on and detached from the fan without requiring the use of tools.

2. The edge of the outer circumferential surface of the outer frame of the fan is clipped between the inner baffle and the at least two hooks, so that the fan duct of the present invention is reliably retained on the fan.

3. The guiding slot of the inner baffle guides the screw-head of the screw that fixes the fan to the heat dissipation device, and the screw-head slightly presses against the inner baffle to prevent the fan duct from shaking.

4. The cutout of the main duct wall further guides air around the fan, thereby improving the heat dissipation effect of the heat dissipation module.

5. Instead of being fixed on the casing of the electronic product, the fan duct of the present invention is fixed on the fan, thereby improving the overall appearance of the casing.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

What is claimed is:

1. A fan duct retained on a fan, the fan having an outer frame, the outer frame forming a plurality of cavities in an outer circumferential surface thereof, the fan duct comprising:
a main duct wall having a fan-end opening adjacent to the fan; and
a connecting wall extending axially and outwardly from the fan-end opening of the main duct wall, the connecting wall having at least two hooks extending radially toward the fan-end opening; wherein
an edge of the outer circumferential surface of the outer frame of the fan matches an inside of the connecting wall, and each of the hooks locks into a corresponding one of the cavities.

2. The fan duct as claimed in claim 1, wherein the connecting wall has two lateral walls, and the at least two hooks are respectively disposed close to top ends of the two lateral walls.

3. The fan duct as claimed in claim 1, wherein the connecting wall has an upper wall and one lateral wall, and the at least two hooks are respectively disposed close to an end of the upper wall and a top end of the lateral wall.

4. The fan duct as claimed in claim 1, wherein the connecting wall has an upper wall, and the at least two hooks are respectively disposed close to two ends of the upper wall.

5. The fan duct as claimed in claim 1, wherein the connecting wall has an upper wall and two lateral walls, the at least two hooks have a quantity of four, two of the hooks are respectively disposed close to two ends of the upper wall, and the other two of the hooks are respectively disposed close to top ends of the two lateral walls.

6. The fan duct as claimed in claim 1, wherein the connecting wall has an upper wall and two lateral walls, the at least two hooks have a quantity of six, two of the hooks are respectively disposed close to two ends of the upper wall, and the other four of the hooks are respectively disposed close to four ends of the two lateral walls.

7. The fan duct as claimed in claim 1, comprising an inner baffle, wherein the inner baffle extends radially from the main duct wall toward the fan-end opening, and the edge of the outer circumferential surface of the outer frame of the fan is clipped between the inner baffle and the at least two hooks.

8. The fan duct as claimed in claim 7, wherein the inner baffle has a guiding slot facing the fan.

9. The fan duct as claimed in claim 7, wherein the main duct wall forms a cutout in a bottom portion of the fan-end opening.

10. The fan duct as claimed in claim 7, wherein the main duct wall has a through hole disposed in an upper portion thereof.
